(19) United States
(12) Patent Application Publication
(10) Pub. No.: US 2014/0362590 A1
(43) Pub. Date: Dec. 11, 2014

(54) ELECTRONIC MODULE, LIGHTING DEVICE AND MANUFACTURING METHOD OF THE ELECTRONIC MODULE

(71) Applicants: Peng Chen, Shenzhen (CN); Xiaomian Chen, Shenzhen (CN); Yaojun Feng, Shenzhen (CN); Hao Li, Shenzhen (CN)

(72) Inventors: Peng Chen, Shenzhen (CN); Xiaomian Chen, Shenzhen (CN); Yaojun Feng, Shenzhen (CN); Hao Li, Shenzhen (CN)

(73) Assignee: OSRAM GMBH, Muenchen (DE)

(21) Appl. No.: 14/238,204

(22) PCT Filed: Aug. 10, 2012
(86) PCT No.: PCT/EP2012/065712

§ 371 Date: Apr. 23, 2014

(30) Foreign Application Priority Data
Aug. 16, 2011 (CN) 201110235306.1

(51) Int. Cl. H05K 1/02; F21V 29/00; H05K 3/28

(52) U.S. Cl. CPC H05K 1/0206; H05K 3/284; F21V 29/004; H05K 2203/1316; H05K 2203/1147; H05K 2203/10; H05K 2201/10106
USPC 362/373; 29/841; 361/707

(57) ABSTRACT

An electronic module to be mounted on a mounting surface may include: a circuit board provided with a heat source, wherein a thermal via is formed through the circuit board and is in thermal contact with the heat source; and a potting material packaging the circuit board at least at the other side opposite to one side of heat source, wherein the potting material has a recess formed in at least part of an area corresponding to the thermal via at the other side of the circuit board and a thermal conductive material, which is thermal-conductively connected to the mounting surface, is filled in the recess.

### RELATED APPLICATIONS

The present application is a national stage entry according to 35 U.S.C. §371 of PCT application No.: PCT/EP2012/065712 filed on Aug. 10, 2012, which claims priority from Chinese application No.: 201110235306.1 filed on Aug. 16, 2011, and is incorporated herein by reference in its entirety.

### TECHNICAL FIELD

Various embodiments relate to an electronic module, a lighting device and a manufacturing method of the electronic module.

### BACKGROUND

Currently, lighting devices have found increasingly wide application in daily life. Most of the electronic modules of these lighting devices have a plastic potting material generally in the form of external housing. Such a potting material ensures that the electronic module meets the dustproof and waterproof requirements in industrial use and prevents the damage of a circuit board and electronic components mounted thereon, especially a LED, during a transportation or installation process.

As shown in FIG. 1, a potting material 4 seals therein the whole of a circuit board 2 provided with a heat source 1, such as an LED, and a thermal via 3 passing through the circuit board 2 is provided under the heat source 1. Such a fully sealed electronic module can be fixed to a mounting surface 6 via a tape 7 adhering to the bottom surface of the potting material 4, such as a double-side adhesive tape. Accordingly, three equivalent thermal resistances may be formed in the electronic module: a first thermal resistance between the heat source 1 and the potting material 4 is mainly the thermal resistance of the circuit board 2 which is equivalent to a thermal resistance generated by a material with a thermal conductivity of 0.2 W/m*K; a second thermal resistance between the potting material 4 and the tape 7 is mainly the thermal resistance of the potting material 4 which is equivalent to a thermal resistance generated by a material with a thermal conductivity of 0.2 W/m*K; and a third thermal resistance between the tape 7 and the mounting surface 6 is mainly the thermal resistance of the tape 7 made of, for example, epoxy resin which is equivalent to a thermal resistance generated by a material with a thermal conductivity of 0.2 W/m*K. However, since the potting material 4 has greater thickness and higher airtightness performance, it is difficult for heat generated by the heat source 1 such as an LED to be dissipated to ambient environment, that is to say, the thermal resistance of the whole electronic module is relatively high, which generally causes low stability of the electronic module and further the possible damage of the whole lighting device.

### SUMMARY

Hence, various embodiments provide a novel electronic module. Such an electronic module which is simple in structure and low in manufacturing cost. Due to the improvement of the potting material of the module, the electronic module according to the present disclosure has lower thermal resistance and good stability.

An electronic module to be mounted on a mounting surface is provided according to the present disclosure, including a circuit board provided with a heat source, wherein a thermal via is formed through the circuit board and is in thermal contact with the heat source; and a potting material packaging the circuit board at least at the other side opposite to one side of heat source, wherein the potting material has a recess formed in at least part of an area corresponding to the thermal via at the other side of the circuit board and a thermal conductive material, which is thermal-conductively connected to the mounting surface, is filled in the recess.

The design idea of the present disclosure lies in breaking through the barrier of the traditional package design of the electronic module. Herein, the potting material exists in the form of potting housing. In order for the heat in the thermal via provided in the circuit board to be better dissipated to its outside, the housing section (hereinafter short for “bottom-surface housing section”) corresponding to the area of thermal via on the bottom surface of the packaged circuit board shall be designed to be as thin as possible. In the most preferred case, the bottom-surface housing section may be removed, such that the thermal via may directly reach the thermal conductive material provided for replacing the bottom-surface housing section and the corresponding area of the bottom surface of the circuit board may be in direct contact with the thermal conductive material rather than enclosed completely and airtightly by the potting housing. Thus, based on such a specific structure as a potting housing and the properties of insulation and thermal conduction of the thermal conductive material, the thermal resistance of the whole electronic module can be advantageously reduced, thereby allowing the electronic module to obtain good stability in an operating state.

In various embodiments, the recess includes at least an area corresponding to the thermal via in position and size, whereby the heat generated by the heat source in an operating state may be directly dissipated to the outside of the circuit board.

In various embodiments, the area of the recess covers up to 90% of that of the other side, viz. the back side of the circuit board. The recess located at the other side of the circuit board is set as wide as possible for providing sufficient heat dissipation pathways. As long as the potting material at the side surface of the electronic module may extend for enclosing the edge of the other side of the circuit board, viz. only covering 10% of the other side of the circuit board from the edge to the inside, better heat dissipation design may be achieved.

In various embodiments, the recess is in communication with the thermal via, such that the heat flow guided by the thermal via may be directly transferred to the thermal conductive material.

In various embodiments, a thin protective layer is provided between the recess and the circuit board. Said thin protective layer may be either part of the potting material or made of other materials with low thermal resistances. The thickness of the thin layer is, for example, less than 0.2 mm. Thus, the high airtightness of the whole electronic module can be ensured while realizing the minimum thermal resistance so as to meet the waterproof and dustproof requirements in industry.

In various embodiments, the thermal conductive material is designed as a step, including a first portion received by the recess, an enlarged second portion extending beyond the recess which covers the potting material. Therefore, the design achieves the effect of dual-layer thermal conduction and improves the airtightness of the electronic module. The material of the first portion and that of the second portion may be either the same or different.

In various embodiments, the thermal conductive material only fills up the recess or the thermal conductive material is filled to extend beyond the recess with same size as that in the recess, and the extended portion of the thermal conductive material is used to be mounted to the mounting surface. In the case where the thermal conductive material only fills up the recess, the thermal conductive material is level with the recess, such that the bottom surface of the electronic module may be adhered evenly to the mounting surface. In the latter case, only the end surface of the thermal conductive material extended beyond the recess may be used as a contact surface to be adhered to the mounting surface, which makes a gap present between the potting material and the mounting surface.

In various embodiments, a front side and a back side of the thermal conductive material are each coated with an adhesive layer for adhering respectively to the bottom surface of the recess and the mounting surface. Coating the double surfaces of the thermal conductive material with the adhesive layer may, on one hand, fix firmly the thermal conductive material in the recess, and on the other hand, make the whole of the electronic module adhere to different mounting surfaces.

In various embodiments, the thermal conductive material is made of an electrical insulating material.

In various embodiments, the thermal conductive material is a filler based on any one of resin, silica gel, and plastic, containing one type of particles or a plurality of particles selected from silicon carbide, aluminum oxide, magnesium oxide, and aluminum nitride. That is to say, the thermal conductive material is a gap filler containing particles with high thermal conductivity. The basic material may be resin, silica gel, or plastic. The particles with high thermal conductivity contained therein may be particles (nanosized particles) of silicon carbide, aluminum oxide, magnesium oxide, or aluminum nitride. Other materials also having properties of high thermal conductivity and electrical insulation may also be considered for manufacturing a thermal conductive material.

In addition, various embodiments provide to a lighting device, including the above electronic module, wherein the heat source is an LED. Certainly, a light engine or the like may be considered to replace the circuit board provided with the LED to form the lighting device.

Further, various embodiment provide a method for manufacturing the above electronic module, including the following steps:

(a) providing a circuit board provided with a heat source, wherein a thermal via is formed through the circuit board and is in thermal contact with the heat source;
(b) putting the circuit board into one mold, wherein the mold is designed to be at least in contact with at least part of the bottom surface of the circuit board provided with the thermal via and a gap is formed between the mold and the rest of the bottom surface of the circuit board;
(c) injecting a potting material to form a recess on at least part of the contacted bottom surface.

Various embodiments further includes step (d), after the mold is removed, in step (d), a thin layer is formed via injection moulding on the recess. Said thin layer may be either part of the potting material or made of other materials. The thickness of the thin layer is less than 0.2 mm.

In various embodiments, there is also provided a method for manufacturing the above electronic module, including the following steps:

(a) providing a circuit board provided with a heat source, wherein a thermal via is formed through the circuit board and is in thermal contact with the heat source;
(b) putting the circuit board into one mold, wherein the mold is designed to form a first gap between the mold and the part of the bottom surface of the circuit board and to form a second gap between the mold and the rest of the bottom surface of the circuit board, the first gap being smaller than the second gap;
(c) injecting a potting material to form a recess at the position corresponding to the first gap.

Thus obtained is either a through recess the bottom surface of which is the bottom surface of the circuit board or a recess the bottom surface of which is a thin film also made of the potting material. The thickness of the thin film is less than 0.2 mm.

Various embodiments further includes step (e) following step (d), in the step (e): filling a solid thermal conductive material in the recess or filling a liquid thermal conductive material in the recess and solidifying the thermal conductive material via standing or heating.

Preferably, in step (e), the thermal conductive material has adhesive layers at two sides facing and away from the circuit board and only fills up the area of the recess. The electronic module thus manufactured may achieve IP65 level.

In various embodiments, there is further included step (f): covering the outside of the filled potting material at the back side of the circuit board with another layer of thermal conductive material. The electronic module thus manufactured may achieve IP66-67 level.

Various embodiments further includes step (g) following step (d): using the liquid thermal conductive material to fill up the recess and to solidify, and further includes step (h) following step (g): adhering a tape to the outside of the filled potting material at the back side of the circuit board. The electronic module thus manufactured may achieve IP66-67 level.

Preferably, the thermal conductive material is made of thermal interface material, and the potting material is rigid plastic.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 is a cross-sectional view of an electronic module according to the prior art;

FIG. 2 is a cross-sectional view of an electronic module according to the present disclosure;

FIG. 3 is a step diagram of a method for manufacturing an electronic module according to the present disclosure;

FIG. 4 is a step diagram of a method for manufacturing an electronic module according to the present disclosure;

FIGS. 5A and 5B are step diagrams of a method for manufacturing an electronic module according to the present disclosure;

FIG. 6 is a step diagram of a method for manufacturing an electronic module according to the present disclosure;

FIG. 7 is a step diagram of a method for manufacturing an electronic module according to the present disclosure;

FIG. 8 is a step diagram of a method for manufacturing an electronic module according to the present disclosure; and

FIG. 9 is a step diagram of a method for manufacturing an electronic module according to the present disclosure.

### DETAILED DESCRIPTION OF THE DRAWINGS

The following detailed description refers to the accompanying drawing that show, by way of illustration, specific details and embodiments in which the disclosure may be practiced.

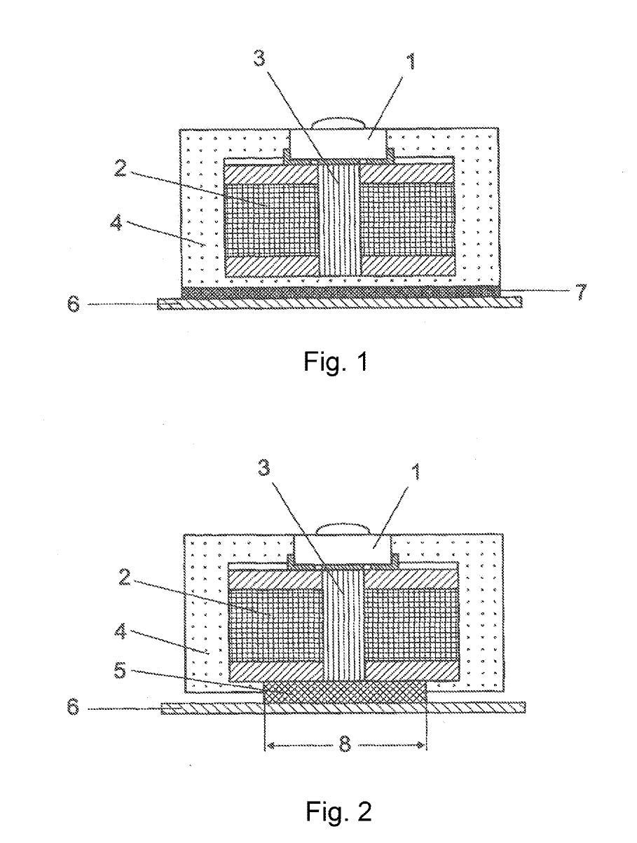

FIG. 2 is a cross-sectional view of an electronic module according to the present disclosure. A circuit board 2 provided with a heat source 1 such as an LED, which may be, for example, an FR 4 printed circuit board, is a dual-layer circuit board having low thermal conductivity similar to conventional plastic, the thermal conductivity thereof being about 0.2 W/m*K. A thermal via 3 is formed through the circuit board 2 and the heat source 1 is located right above the thermal via 3 and in direct thermal contact with the same, whereby the heat generated by the heat source 1 in an operating state may be dissipated via the thermal via 3 to the outside of the circuit board 2. In order to obtain a good thermal conductive effect, a thermal conductive dielectric is generally filled in the thermal via 3. The potting material 4 of the packaged circuit board 2 is generally rigid plastic, the thermal resistance of which is equivalent to that generated by a material with a thermal conductivity of 0.2 W/m*K. Other materials with low thermal resistances may also be considered as a potting material. When being installed, the electronic module is generally fixed to a mounting surface 6 via a tape 7 (see FIG. 1).

The difference as compared with FIG. 1 lies in improving the side distant from the heat source 1 of the potting material 4 of the electronic module according to the present disclosure, which is designing part of the potting material 4 corresponding to the area of the thermal via 3, namely a bottom-surface housing section, as thin as possible so as to form a recess 8. A protective thin layer 9 is provided between the recess and the circuit board 2. The protective thin layer 9 may be either part of the potting material 4 or made of other materials with low thermal resistances. In the most preferred case, the thickness of the protective thin layer 9 is less than 0.2 mm. Thus, the high airtightness of the whole electronic module can be ensured while realizing the minimum thermal resistance of the electronic module so as to meet the waterproof and dustproof requirements in industry. The back side of the circuit board 2 may directly constitute a bottom surface of the recess 8, whereby the heat in the thermal via 3 may be effectively dissipated to the outside.

The thermal resistance of the electronic module according to the present disclosure may be calculated by the formula: thermal resistance=thickness/(area*thermal conductivity). Without affecting the packaging, the thermal resistance of the potting material 4 may be reduced satisfactorily by reducing the thickness of the potting material 4 on the bottom surface and increasing the corresponding area of the recess 8. The area of the recess 8 is preferably 90% of that of the whole electronic module. The recess 8 located at the back side of the circuit board 2 is set to be as large as possible so as to provide sufficient heat dissipation pathways. As long as the potting material 4 at the side surface of the electronic module may extend for enclosing the edge of the back side of the circuit board 2, viz. for example, only covering 10% of the back side of the circuit board 2 from the edge to the inside, the best heat dissipation design may be achieved.

In order to ensure the packaging effect and further improve thermal performance, a thermal conductive material 5 made of thermal interface material (TIM) may be filled in the recess 8. The thermal conductive material 5 with an electrical insulation property is, for example, a filler based on silica gel. The thickness of the thermal conductive material 5 shall be equal to or larger than the depth of the recess 8. In order to make the thermal conductive material 5 in firm thermal contact with the bottom surface of the recess 8, both the front side and the back side thereof may be coated with adhesive layers for adhering respectively to the bottom surface of the recess 8 and the mounting surface 6. Another possible case is: adhering a double-side-adhesive second layer of thermal interface material (not shown) to a side where the thermal conductive material 5 faces the mounting surface 6. The area of the second portion of thermal interface material shall be larger than that of the thermal conductive material 5 and enlarged second portion extending beyond the recess 8 which covers the potting material 4 for forming a step thermal conductive structure, thereby ensuring good airtight and thermal conductive effects.

The thermal conductive material 5 is a filler containing particles with high thermal conductivity. The basic material may be resin, silica gel, or plastic. The particles with high thermal conductivity contained therein may be particles (nanosized particles) of silicon carbide, aluminum oxide, magnesium oxide, or aluminum nitride. Other materials also having properties of high thermal conductivity and electrical insulation may also be considered for manufacturing a thermal conductive material.

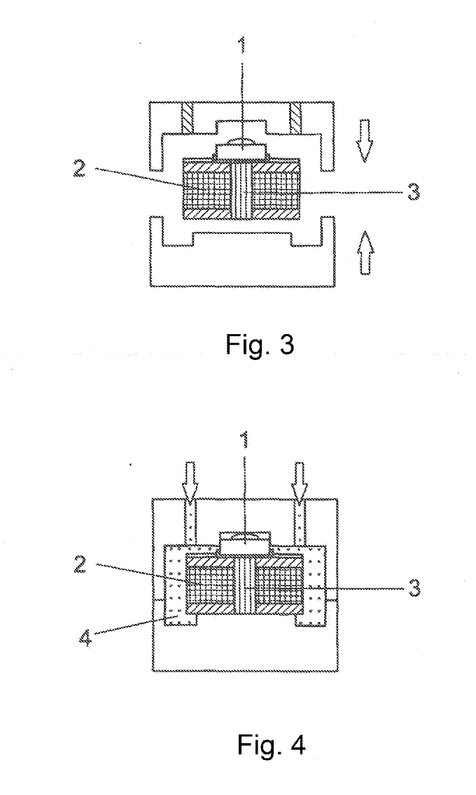

FIGS. 3-9 are step diagrams of a method for manufacturing an electronic module according to the present disclosure according to the present disclosure.

As shown in FIG. 3, the circuit board 2 is provided with the heat source 1 mounted thereon, wherein the thermal via 3 under the heat source 1 is formed through the circuit board 2, and the heat source 1 is in thermal contact with the thermal via 3. The circuit board 2 to be mounted is put in the middle of the package mold, and said mold is designed to be at least in contact with at least part of the bottom surface of the circuit board 2 provided with the thermal via 3 and to form a gap between the mold and the rest of the bottom surface of the circuit board 2. Then, the upper mold and the lower mold snap together and the potting material is injected thereto such that the recess 8 is formed on at least part of the contacted bottom surface.

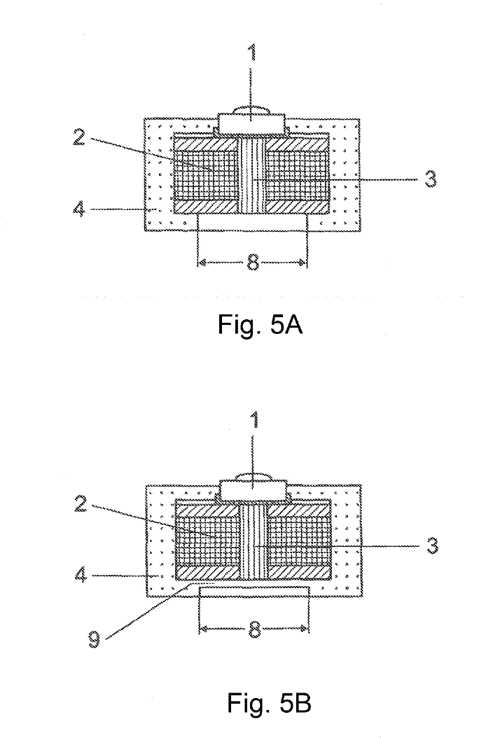

It can be seen from FIG. 4 that, a liquid potting material 4 such as melted rigid plastic is injected by an injection moulding process into the mold via the feeding inlet of the mold. After cooling and removing the mold, two packaged bodies with different packaging effects are obtained as shown in FIGS. 5a and 5b. The packaged body in FIG. 5a semi-encloses the circuit board 2 therein. The bottom surface of the circuit board 2 is exposed outside of the potting material 4, that is to say, the bottom surface of the recess 8 formed on the bottom surface of the packaged body is the bottom surface of the circuit board 2. In step (d) as shown in FIG. 5b, after the removal of the mold, the protective thin film is formed by injection moulding on the recess 8. Said protective thin layer 9 may be either part of the potting material 4 or made of other materials. The thickness of the protective thin layer 9 is less than 0.2 mm.

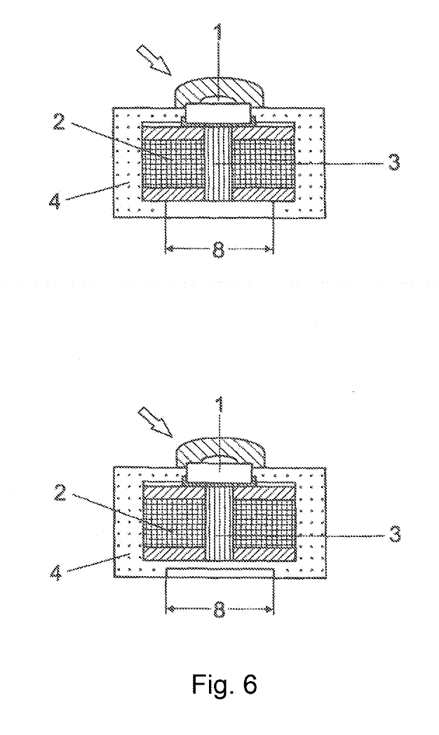

According to another manufacturing method, a certain space is preserved at the recess 8 when designing the mold, viz. the mold is designed to form a first gap between the mold and part of the bottom surface of the circuit board 2 and to form a second gap between the mold and the rest of the bottom surface of the circuit board 2, the first gap being smaller than the second gap. Thus, the protective thin film 9 is formed on the recess 8 after the removal of the mold. The protective thin film 9 constitutes the bottom surface of the recess 8. As shown in FIG. 6, a transparent housing is mounted at the light emitting side of the heat source 1 to provide protection.

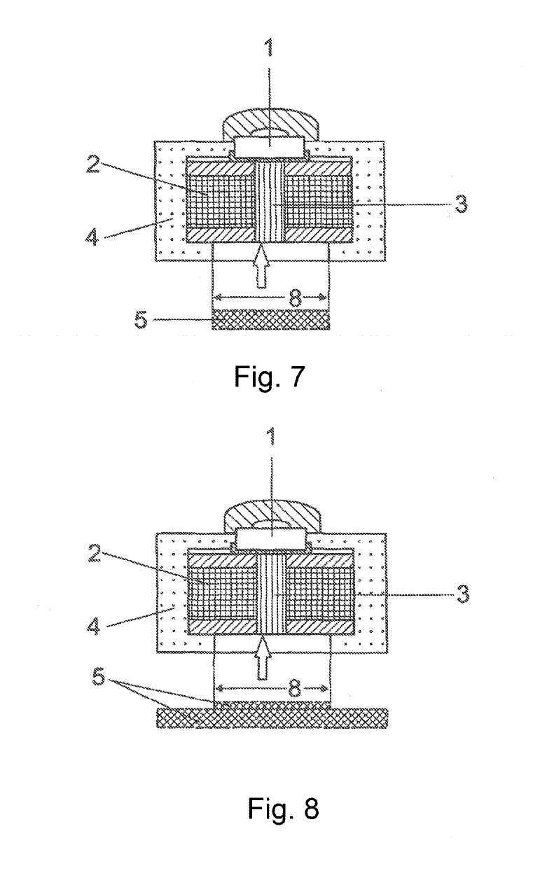

FIG. 7 to FIG. 9 show three ways to mount the thermal conductive material 5. In FIG. 7, a solid thermal conductive material 5 made of thermal interface material just fills up the recess 8 or the liquid thermal conductive material 5 is filled in the recess 8, and the thermal conductive material 5 is solidified via standing or heating. The thermal conductive material 5 is designed to have double-side adhesiveness, such that it can be adhered firmly to the bottom surface of the recess 8. In this embodiment, it is adhered directly to the bottom surface of the circuit board 2. The airtightness of the electronic module formed in this way achieves IP65 level, wherein the back side of the circuit board 2 shall be coated with a waterproof layer covering a copper film layer on the bottom surface of the circuit board 2.

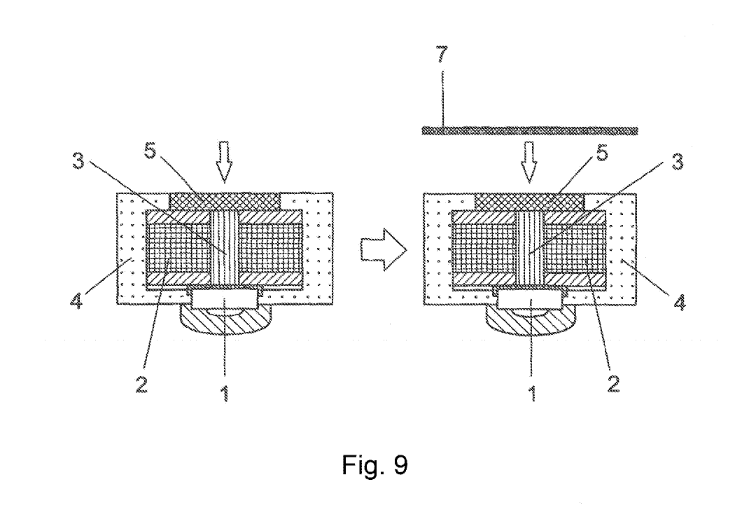

In FIG. 8, the thermal conductive material 5 covers the whole area of the back side of the circuit board 2, wherein the upper part of the thermal conductive material 5 is filled in the recess 8 and the lower part thereof is adhered to the bottom surface of the potting material 4 at two sides of the recess 8, viz. after the step as shown in FIG. 7, another layer of thermal conductive material 5 covers the outside of the filled potting material 4 at the back side of the circuit board 2. The airtightness of the electronic module formed in this way achieves IP66-67 level. In FIG. 9, a liquid thermal interface material such as melted organic silicone resin is used directly to fill the recess 8. The liquid thermal interface material is solidified to form the thermal conductive material 5, and the tape 7 is provided on the bottom surface of the electronic module for adhering firmly the electronic module to the mounting surface 6. The airtightness of the electronic module formed in this way achieves IP66-67 level.

Preferably, the thermal interface material for manufacturing the thermal conductive material is an electrical insulating material. Particularly preferably, the thermal conductive material 5 is a filler based on silica gel. Organic silicone resin or silica gel doped with silica particles or ceramic particles may be selected for manufacturing the thermal conductive material according to the present disclosure. Other materials also having properties of high thermal conductivity and electrical insulation may also be considered for manufacturing the thermal conductive material.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

### LIST OF REFERENCE SIGNS

1 heat source
2 circuit board
3 thermal via
4 potting material
5 thermal conductive material
6 mounting surface
7 tape
8 recess
9 protective thin film

1. An electronic module to be mounted on a mounting surface, comprising:
a circuit board provided with a heat source, wherein a thermal via is formed through the circuit board and is in thermal contact with the heat source; and
a potting material packaging the circuit board at least at the other side opposite to one side of heat source, wherein the potting material has a recess formed in at least part of an area corresponding to the thermal via at the other side of the circuit board and a thermal conductive material, which is thermal-conductively connected to the mounting surface, is filled in the recess.

2. The electronic module according to claim 1, wherein the recess comprises at least an area corresponding to the thermal via in position and size.

3. The electronic module according to claim 2, wherein the area of the recess covers up to 90% of that of the other side of the circuit board.

4. The electronic module according to claim 3, wherein the recess is in communication with the thermal via.

5. The electronic module according to claim 3, wherein a thin protective layer is provided between the recess and the circuit board.

6. The electronic module according to claim 5, wherein the thickness of the thin protective layer is less than 0.2 mm.

7. The electronic module according to claim 1, wherein the thermal conductive material is designed as a step, comprising a first portion received by the recess, and an enlarged second portion extending beyond the recess which covers the potting material.

8. The electronic module according to claim 1, wherein the thermal conductive material only fills up the recess or the thermal conductive material is filled to extend beyond the recess with same size as that in the recess, and the extended portion of the thermal conductive material is used to be mounted to the mounting surface.

9. The electronic module according to claim 7, wherein a front side and a back side of the thermal conductive material are each coated with an adhesive layer for adhering respectively to the bottom surface of the recess and the mounting surface.

10. The electronic module according to claim 9, wherein the thermal conductive material is made of an electrical insulating material.

11. The electronic module according to claim 10, wherein the thermal conductive material is a filler based on any one of resin, silica gel, and plastic, containing one type of particles or a plurality of particles selected from silicon carbide, aluminum oxide, magnesium oxide, and aluminum nitride.

12. The electronic module according to claim 1,
wherein the heat source is an LED.

13. A method for manufacturing an electronic module the electronic module comprising:
a circuit board provided with a heat source, wherein a thermal via is formed through the circuit board and is in thermal contact with the heat source; and
a potting material packaging the circuit board at least at the other side opposite to one side of heat source, wherein the potting material has a recess formed in at least part of an area corresponding to the thermal via at the other side of the circuit board and a thermal conductive material, which is thermal-conductively connected to the mounting surface, is filled in the recess,
the method comprising:
providing a circuit board provided with a heat source, wherein a thermal via is formed through the circuit board and is in thermal contact with the heat source;
putting the circuit board into one mold, wherein the mold is designed to be at least in contact with at least part of the bottom surface of the circuit board provided with the thermal via and to form a gap between the mold and the rest of the bottom surface of the circuit board; and
injecting a potting material to form a recess on at least part of the contacted bottom surface.

14. A method for manufacturing an electronic module the electronic module comprising:
a circuit board provided with a heat source, wherein a thermal via is formed through the circuit board and is in thermal contact with the heat source; and
a potting material packaging the circuit board at least at the other side opposite to one side of heat source, wherein the potting material has a recess formed in at least part of an area corresponding to the thermal via at the other side of the circuit board and a thermal conductive material, which is thermal-conductively connected to the mounting surface, is filled in the recess,
the method comprising:
providing a circuit board provided with a heat source, wherein a thermal via is formed through the circuit board and is in thermal contact with the heat source;
putting the circuit board into one mold, wherein the mold is designed to form a first gap between the mold and the part of the bottom surface of the circuit board and to form a second gap between the mold and the rest of the bottom surface of the circuit board, the first gap being smaller than the second gap; and
injecting a potting material to form a recess at the position corresponding to the first gap.

15. The method according to claim 13, further comprising: after the mold is removed forming a thin protective layer via injection moulding on the recess.

16. The method according to claim 15, further comprising: filling a solid thermal conductive material in the recess or filling a liquid thermal conductive material in the recess and solidifying the thermal conductive material via standing or heating.

17. The method according to claim 16, wherein in fillin, the thermal conductive material has adhesive layers at two sides facing and away from the circuit board and only fills up the area of the recess.

18. The method according to claim 17, further comprising: covering the outside of the filled potting material at the back side of the circuit board with another layer of thermal conductive material.

19. The method according to claim 15, further comprising: using the liquid thermal conductive material to fill up the recess and to solidify, and adhering a tape to the outside of the filled potting material at the back side of the circuit board.
